(19) United States
(12) Patent Application Publication
(10) Pub. No.: US 2010/0046155 A1
(43) Pub. Date: Feb. 25, 2010

(54) INFORMATION PROCESSING UNIT

(75) Inventors: Haruka KANEKO, Kyoto (JP); Shintaro TANAKA, Osaka (JP); Hitoshi NAKATANI, Osaka (JP); Yoshiaki NAGAMURA, Osaka (JP)

Correspondence Address: HAMRE, SCHUMANN, MUELLER & LARSON P.C., P.O. BOX 2902-0902, MINNEAPOLIS, MN, 55402, US

(73) Assignee: PANASONIC CORPORATION, Osaka (JP)

(21) Appl. No.: 12/538,395

(22) Filed: Aug. 10, 2009

(30) Foreign Application Priority Data
Aug. 19, 2008 (JP) 2008-211002

(51) Int. Cl. H05K 5/00

(52) U.S. Cl. 361/679.27

(57) ABSTRACT

An information processing unit of the present invention includes hollow portions on a first casing side and protrusion portions on a second casing side, and the portions on both sides can be fitted. Accordingly, even when a notebook PC accidentally is dropped on the ground or the like, it is possible to reduce changes in the relative position of the second casing with respect to the first casing, which reduces a load applied to a hinge portion. Therefore, it is possible to prevent the hinge portion from being broken.

### BACKGROUND OF THE INVENTION

1. Field of the Invention

The present invention relates to a portable information processing unit such as a notebook personal computer (hereinafter, referred to as a notebook PC).

2. Description of Related Art

In recent years, notebook PCs include a first casing including various circuit boards, a keyboard, and the like, and a second casing including a liquid crystal display as disclosed in JP 2007-241511A, for example. The second casing is supported so as to be pivotable with respect to the first casing by a hinge mechanism.

Notebook PCs have portability; thus, there is a possibility of such PCs accidentally being dropped on the ground or the like. In order to prevent the second casing from coming into contact with the ground or the like first when a notebook PC accidentally is dropped on the ground or the like, a configuration in which the end portion of the first casing protrudes relative to the end portion of the second casing has been proposed. However, in the case of a configuration in which the end portion of the first casing protrudes relative to the end portion of the second casing, the relative position of the second casing with respect to the first casing tends to be misaligned due to the inertia caused by an impact when dropped. At this time, an impact load is applied to the hinge mechanism, which may damage or disable the hinge mechanism.

### SUMMARY OF THE INVENTION

Therefore, with the foregoing in mind, it is an object of the present invention to provide an information processing unit that can suppress misalignment of the relative position between the first casing and the second casing caused by an impact when dropped, that can reduce a load applied to the hinge mechanism, and that can prevent the hinge mechanism from being broken.

An information processing unit of the present invention is an information processing unit provided with a second casing including a display unit, a first casing including an input unit capable of inputting information to be displayed on the display unit, and a hinge mechanism that supports the second casing and the first casing so as to be pivotable. The information processing unit includes a first protrusion portion that is disposed in a protruding manner in a direction substantially orthogonal to a display face of the display unit of the second casing, a hollow portion that is formed on the first casing and that the protrusion portion can fit into, and a second protrusion portion that is formed in a protruding manner in a direction along a plane of the display face of the display unit, in a position of a cover member of the hinge mechanism facing the first casing.

According to the present invention, it is possible to suppress misalignment of the relative position between the first casing and the second casing caused by an impact when dropped, to reduce a load applied to the hinge mechanism, and to prevent the hinge mechanism from being broken.

### BRIEF DESCRIPTION OF THE DRAWINGS

FIG. 1 is a perspective view of an information processing unit (in a first state) in an embodiment.

FIG. 2 is a perspective view of the information processing unit (in a second state) in an embodiment.

FIG. 3 is a plan view of the information processing unit (in the second state) in an embodiment.

FIG. 4 is a side view of the information processing unit (in the second state) in an embodiment.

FIG. 5 is a perspective view of a relevant part of a second casing.

FIG. 6 is a perspective view of a relevant part of a first casing.

FIG. 7 is a perspective view of a relevant part in the vicinity of a hinge portion.

### DETAILED DESCRIPTION OF THE INVENTION

Hereinafter, the present invention will be described by way of illustrative embodiments with reference to the drawings.

An information processing unit of the present invention is an information processing unit provided with a second casing including a display unit, a first casing including an input unit capable of inputting information to be displayed on the display unit, and a hinge mechanism that supports the second casing and the first casing so as to be pivotable. The information processing unit includes a first protrusion portion that is disposed in a protruding manner in a direction substantially orthogonal to a display face of the display unit of the second casing, a hollow portion that is formed on the first casing and that the protrusion portion can fit into, and a second protrusion portion that is formed in a protruding manner in a direction along a plane of the display face of the display unit, in a position of a cover member of the hinge mechanism facing the first casing.

The information processing unit of the present invention may be embodied as in the following with the above-described configuration as the basic configuration.

The information processing unit of the present invention can be configured such that the first protrusion portion is formed in an elongated shape that is substantially parallel to a short side direction of a display area of the display unit. With this configuration, it is possible to limit the relative position of the second casing with respect to the first casing, which can reduce the misalignment of a relative position between the first casing and the second casing caused by an impact when dropped. Therefore, it is possible to prevent the hinge mechanism from being broken.

### Embodiment

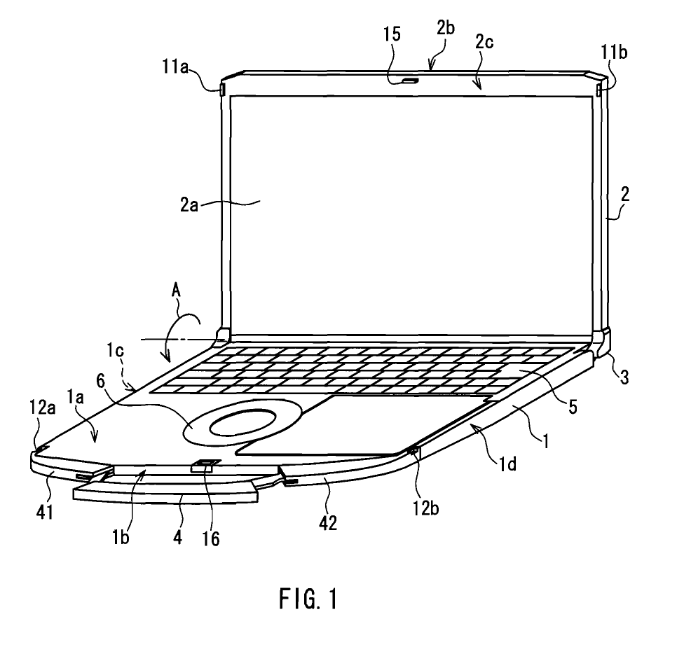

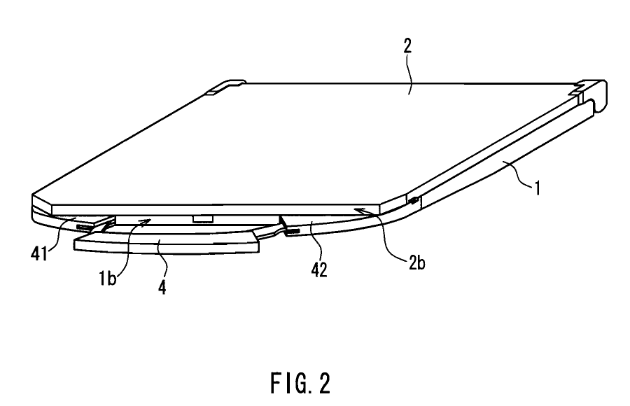

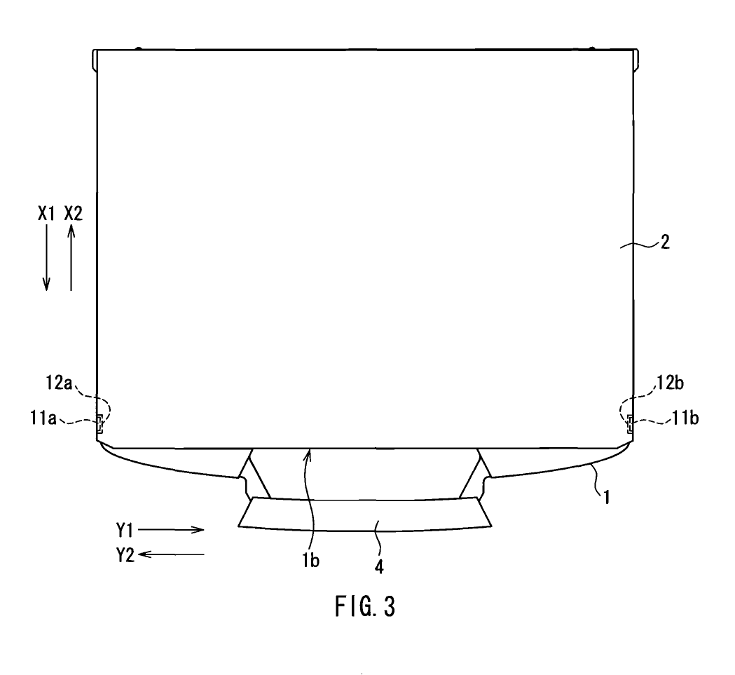

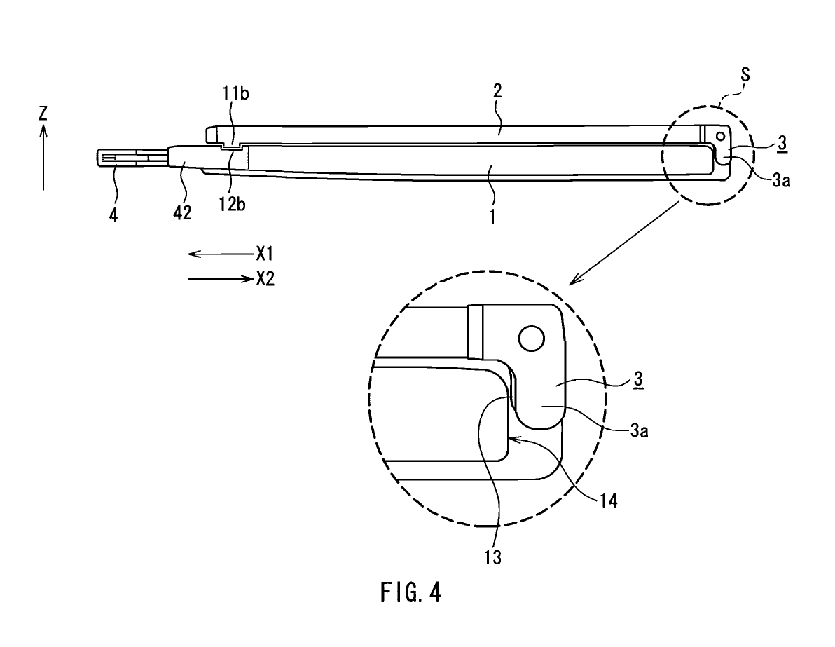

FIG. 1 is a perspective view showing an external view of an information processing unit of the present embodiment and shows a first state of a notebook PC that is an example of an information processing unit. FIG. 2 illustrates a second state of the notebook PC of the present embodiment. FIG. 3 is a plan view showing the notebook PC in the second state. FIG. 4 is a side view of the notebook PC in the second state. It should be noted that although the present embodiment is described using a notebook PC as an example of an information processing unit, it is sufficient if the unit is an information processing unit at least including a first casing and a second casing that are connected mechanically to each other, such as a portable phone terminal or a portable electronic game machine.

As shown in FIG. 1, the notebook PC includes a first casing 1 and a second casing 2. The first casing 1 contains a circuit board on which various electrical elements are mounted, a hard disk drive, and the like. The second casing 2 includes a liquid crystal display 2a. The first casing 1 and the second casing 2 are supported by a hinge portion 3 so as to be pivotable with respect to each other. The second casing 2 can shift to the second state as shown in FIG. 2 by being pivoted in the direction indicated by arrow A from a position shown in FIG. 1 (the first state). The second state is a state in which the liquid crystal display 2a closely faces a keyboard 5.

When a face of the first casing that faces the second casing in the second state is defined as a “top side”, a top face 1a of the first casing 1 includes the keyboard 5 and a pointing device 6. An operation for inputting various characters can be performed with the keyboard 5. An operation for moving a cursor displayed on the liquid crystal display 2a to a desired position can be performed with the pointing device 6.

Further, when a handle 4 side is defined as a “front side” in the second state, support members 41 and 42, which support the handle 4, are fixed on a lateral face 1b on the front side of the first casing 1 (hereinafter, referred to as front face of the first casing). The support members 41 and 42 protrude from the front face 11b (as shown in FIGS. 3 and 4).

Projection portions 11a and 11b are provided in the vicinity of a top face 2b of a front face 2c of the second casing 2. The protrusion portions 11a and 11b are provided in the vicinity of both ends in the long side direction of the second casing 2, respectively. Note that, although the protrusion portions 11a and 11b are configured as members different from the second casing 2, it is possible to form the portions so as to be integrated with the second casing 2.

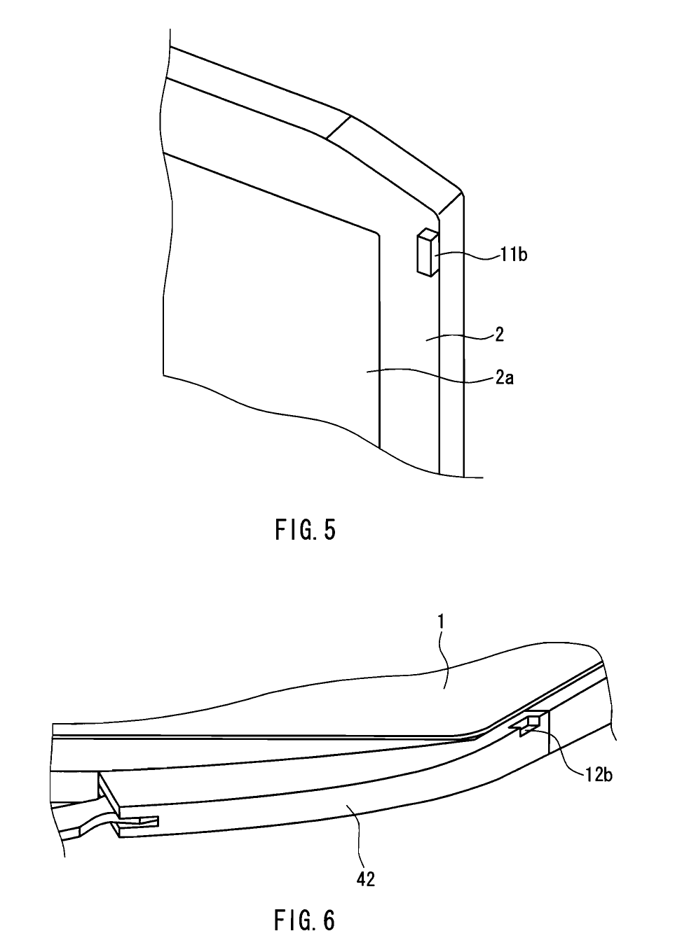

FIG. 5 is an enlarged perspective view in the vicinity of the protrusion portion 11b of the second casing 2. The protrusion portions 11a and 11b are formed in a rectangular parallelepiped shape or a substantially semi-cylindrical shape. The protrusion portions 11a and 11b are formed on the second casing 2 such that the long side direction thereof is along the short side direction of the second casing 2.

A lug portion 15 is formed substantially in the center of the top end of the front face 2c of the second casing 2. Meanwhile, an engaged portion 16 is formed in the vicinity of the end portion of the top face 1a of the first casing 1. When the notebook PC is in the second state, the lug portion 15 can engage with the engaged portion 16. By the lug portion 15 engaging with the engaged portion 16, it is possible to limit the position of the second casing 2 with respect to the first casing 1. Note that an engagement cancellation button (not shown) provided to the engaged portion 16 is operated in order to cancel the engaged state of the lug portion 15 and the engaged portion 16. By operating the engagement cancellation button, the engagement of the engaged portion 16 and the lug portion 15 is cancelled. By cancelling the engagement of the engaged portion 16 and the lug portion 15, the second casing 2 can be pivotable with respect to the first casing 1.

The hinge portion 3 includes a spindle (not shown), a load applying mechanism (not shown), and a cover member 3a. The spindle pivotably supports the first casing 1 and the second casing 2. The load applying mechanism applies a load to the first casing 1 or the second casing 2 so that the casing pivots. The cover member 3a covers the spindle, the load applying mechanism, and the like. The cover member 3a preferably is formed of a resin material having elastomeric properties. The cover member 3a is preferably formed of internally plasticized polybutylene terephthalate, for example. Further, a protrusion portion 13 is formed on the cover member 3a as shown in an enlarged view of a reference sign “S” in FIG. 4 and in a perspective view of a relevant part in FIG. 7. The protrusion portion 13 is formed in a position in which the portion faces a limiting face 14 of the first casing 1 when the notebook PC is in the second state, as shown in FIG. 4. Note that a protrusion portion similar to the protrusion portion 13 is formed on a cover member of a hinge portion on the other side, which is not shown in the drawings.

A user can hold the handle 4 with their hand. The user can hand-carry the notebook PC by holding the handle 4 with their hand. Both ends in the long side direction of the handle 4 are supported by the support members 41 and 42, respectively.

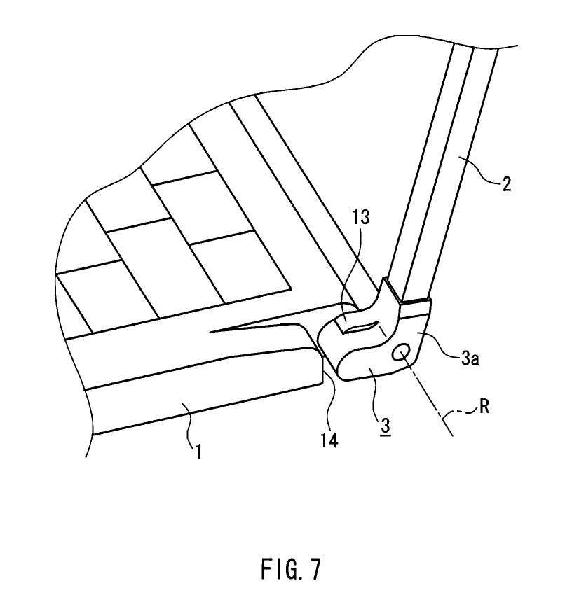

The support member 41 is disposed from the front face 1b to part of a lateral face 1c of the first casing 1, continuously. The support member 42 is disposed from the front face 1b to part of a lateral face id of the first casing 1, continuously. A hollow portion 12a is formed in the support member 41 in the vicinity of the lateral face 1c. A hollow portion 12b is formed in the support member 42 in the vicinity of the lateral face 1d (see FIG. 6). The protrusion portion 11a can fit into the hollow portion 12a. The protrusion portion 11b can fit into the hollow portion 12b. By the protrusion portion 11a fitting into the hollow portion 12a, it is possible to limit the position of the second casing 2 in the directions indicated by arrows X1, X2, and Y1 (see FIG. 3). Also, by the protrusion portion 11b fitting into the hollow portion 12b, it is possible to limit the position of the second casing 2 from shifting in the directions indicated by arrows X1, X2, and Y2 (see FIG. 3).

When the notebook PC configured as described above is dropped on the ground or the like in a position in which the front face 1b is facing vertically downward (the direction in which the PC is dropped is the direction indicated by arrow X1), since the handle 4 and the support members 41 and 42 are protruding from the first casing 1 (as shown in FIG. 3), these portions come into contact with the ground or the like before the second casing 2. Immediately after the handle 4 and the like comes into contact with the ground or the like, the second casing 2 tends to be displaced in the direction indicated by arrow X1 due to the inertia caused by an impact when dropped. However, since the protrusion portion 11a is fitted in the hollow portion 12a and the protrusion portion 11b is fitted in the hollow portion 12b, the relative position of the second casing 2 with respect to the first casing 1 is limited. Therefore, the second casing 2 will not be displaced greatly in the direction indicated by arrow X1 easily. Furthermore, the protrusion portion 13 formed on the cover member 3a abuts against an abutting face 14 of the first casing 1 as shown in FIG. 4, with the added resilience of the cover member 3a being formed of a resin having elastomeric properties. Thus, the relative position of the second casing 2 with respect to the first casing 1 is not greatly changed easily. Therefore, it is possible to reduce a load applied to the hinge portion 3 due to an impact when the PC is dropped.

Even when the notebook PC is dropped on the ground or the like in a position other than the position in which the front face 1b is facing vertically downward, the second casing 2 will not be displaced greatly in the direction indicated by arrows X1, X2, Y1, or Y2 easily. This is because, as for the second casing 2, the protrusion portion 11a is fitted in the hollow portion 12a, and the protrusion portion 11b is fitted in the hollow portion 12b; thus, the relative position of the second casing 2 with respect to the first casing 1 is limited. Also, since the lug portion 15 and the engaged portion 16 are engaged, the relative position of the second casing 2 with respect to the first casing 1 in the direction of arrow Z (see FIG. 4) will not be greatly changed easily. Therefore, it is possible to reduce a load applied to the hinge portion 3 due to an impact when the PC is dropped.

According to the present embodiment, since the protrusion portion 11a of the second casing 2 can fit into the hollow portion 12a of the first casing 1, the protrusion portion 11b of the second casing can fit into the hollow portion 12b of the first casing. Therefore, when the notebook PC is accidentally dropped on the ground or the like, changes in the relative position of the second casing 2 with respect to the first casing 1 can be reduced. Therefore, it is possible to reduce a load applied to the hinge portion 3, which can prevent the hinge portion 3 from being broken.

Furthermore, since the protrusion portion 11a is fitted in the hollow portion 12a, the protrusion portion 11b is fitted in the hollow portion 12b, and the lug portion 15 is engaged with the engaged portion 16, even when the notebook PC is dropped on the ground or the like in any position, it is possible to reduce changes in the relative position of the second casing 2 with respect to the first casing 1. Therefore, it is possible to reduce a load applied to the hinge portion 3, which can prevent the hinge portion 3 from being broken.

Moreover, the cover member 3a of the hinge portion 3 includes the protrusion portion 13, and the first casing 1 includes the abutting face 14. Therefore, when the notebook PC accidentally is dropped on the ground or the like, it is possible to reduce changes in the relative position of the second casing 2 with respect to the first casing 1. Therefore, it is possible to reduce a load applied to the hinge portion 3, which can prevent the hinge portion 3 from being broken.

Note that, when the notebook PC in the second state is held by the handle 4, and then the hand is removed from the handle 4 in that state so that the notebook PC is dropped on the ground or the like, an impact applied at that time is often applied in a parallel direction to the direction in which the PC was being held, in general. In the present embodiment, the protrusion portions 11a and 11b are elongated and are arranged such that the long side direction of the protrusion portions 11a and 11b is substantially parallel to the short side direction of the liquid crystal display 2a, thus providing a configuration in which damage to the elongated protrusion portions 11a and 11b themselves is suppressed. However, it is possible to arrange the long side direction of the protrusion portions 11a and 11b to be substantially parallel to the long side direction of the liquid crystal display 2a. Furthermore, although the shape of the protrusion portions 11a and 11b in the present embodiment is an elongated shape, the shape can be a circular cylinder, a triangular prism, or the like. In this case, it is sufficient to provide the hollow portions 12a and 12b, in which the shape of the protrusion portions 11a and 11b fits.

Although the present embodiment has a configuration in which the second casing 2 includes the protrusion portions 11a and 11b, and the first casing 1 side includes the hollow portions 12a and 12b, the embodiment can be configured such that the second casing 2 includes a hollow portion, and the first casing 1 side includes a protrusion portion.

Furthermore, although the support members 41 and 42 include the hollow portions 12a and 12b in the present embodiment, the first casing 1 can include the hollow portions 12a and 12b.

Furthermore, although the protrusion portion 13 is provided to part of the cover member 3a in the axial direction of a rotation shaft R in the present embodiment as shown in FIG. 7, the protrusion portion 13 can be provided to the entire cover member 3a in the axial direction of the rotation shaft R.

Furthermore, the protrusion portions 11a and 11b in the present embodiment are examples of a first protrusion portion of the present invention. Also, the protrusion portion 13 in the present embodiment is an example of a second protrusion portion of the present invention.

An information processing unit of the present invention is useful for a portable information processing unit such as a notebook PC.

The following appendixes are disclosed regarding the present embodiment.

### (Appendix 1)

An information processing unit provided with a second casing includes a display unit and a first casing including an input unit capable of inputting information to be displayed on the display unit, the second casing and the first casing being supported by a hinge mechanism so as to be pivotable with respect to each other, the information processing unit includes:

a first protrusion portion that is disposed in a protruding manner in a direction substantially orthogonal to a display face of the display unit of the second casing;

a hollow portion that is formed on the first casing and that the protrusion portion can fit into; and

a second protrusion portion that is formed in a protruding manner in a direction along a plane of the display face of the display unit, in a position of a cover member of the hinge mechanism facing the first casing.

### (Appendix 2)

The information processing unit according to appendix 1, wherein the first protrusion portion is formed in an elongated shape that is substantially parallel to a short side direction of a display area of the display unit.

The invention may be embodied in other forms without departing from the spirit or essential characteristics thereof. The embodiments disclosed in this application are to be considered in all respects as illustrative and not limiting. The scope of the invention is indicated by the appended claims rather than by the foregoing description, and all changes which come within the meaning and range of equivalency of the claims are intended to be embraced therein.

What is claimed is:

1. An information processing unit comprising,
a second casing including a display unit;
a first casing including an input unit capable of inputting information to be displayed on the display unit; and
a hinge mechanism that supports the second casing and the first casing so as to be pivotable;
wherein a first protrusion portion that is disposed in a protruding manner in a direction substantially orthogonal to a display face of the display unit of the second casing;
a hollow portion that is formed on the first casing and that the protrusion portion can fit into; and
a second protrusion portion that is formed in a protruding manner in a direction along a plane of the display face of the display unit, in a position of a cover member of the hinge mechanism facing the first casing.

2. The information processing unit according to claim 1, wherein the first protrusion portion is formed in an elongated shape that is substantially parallel to a short side direction of a display area of the display unit.
